(19) United States
(12) Patent Application Publication
(10) Pub. No.: US 2024/0121949 A1
(43) Pub. Date: Apr. 11, 2024

(54) SEMICONDUCTOR DEVICE AND MANUFACTURING METHOD THEREFOR

(71) Applicant: INDUSTRY-ACADEMIC COOPERATION FOUNDATION GYEONGSANG NATIONAL UNIVERSITY, Jinju-si (KR)

(72) Inventor: Jungsik KIM, Jinju-si (KR)

(21) Appl. No.: 18/005,831

(22) PCT Filed: Jun. 23, 2021
(86) PCT No.: PCT/KR2021/007905

§ 371 Date: Jan. 17, 2023

(30) Foreign Application Priority Data
Aug. 18, 2020 (KR) 10-2020-0103025

(51) Int. Cl. H10B 12/00

(52) U.S. Cl. CPC H10B 12/488; H10B 12/02

(57) ABSTRACT

A method for manufacturing a semiconductor device is disclosed. The manufacturing method comprises the steps of: preparing a substrate on which a unit cell is formed, forming a mask for forming a passing word-line, on the substrate; performing primary etching to form a vertical trench deeper than the lower end of the unit cell on the substrate having the mask formed thereon; performing secondary etching to have an overhang structure on a lower end region of the vertical trench; forming an insulating layer on the trench having the overhang structure; and filling, with a conductive material, the trench having the insulating layer formed thereon, to form a passing word-line (PWL).

### TECHNICAL FIELD

The disclosure relates to a semiconductor device and a manufacturing method thereof. More particularly, the disclosure relates to a semiconductor device having overhang protruding structure in a passing word-line (PWL) area and a manufacturing method thereof.

### BACKGROUND ART

A semiconductor memory device may be a semiconductor device used for the purpose of storing data in PCs, mobile phones, servers, and the like, and may include various types such as, for example, and without limitation, a DRAM, a ROM, a flash device, a FeRAM, a PRAM, and the like.

Among the above-described semiconductor memory devices, the DRAM, as a type of RAM which is simple in structure and easy to integrate, is widely used as a high-capacity short-term memory device. The DRAM may be configured as a cell device which records information of 1 byte using one transistor and one capacitor (1T/1C).

Recently with a DRAM process being reduced to early 10 nm, there are problems such as a row-hammer error occurring in which a write operation is carried out with a specific cell when a neighbor cell is accessed, retention occurring which is time in which data is maintained after the write operation, and the write operation being slowed.

To solve the above-described problems, an ion implantation process and the like are being performed from among processes that form the passing word-line in the related art, but the process described above has the problem of complicating the DRAM process, increasing the process time, and the like.

### DISCLOSURE

### Technical Problem

Accordingly, an object of the disclosure is in providing a semiconductor device having an overhang protruding structure in a passing word-line (PWL) area and a manufacturing method thereof.

### Technical Solution

In accordance with the disclosure for achieving the object described above, a manufacturing method of a semiconductor device includes preparing a substrate on which a unit cell is formed, forming a mask for forming a passing word-line on the substrate, performing a first etching for a vertical trench, which is deeper than a lower end of the unit cell, to be formed at the substrate on which the mask is formed, performing a second etching so as to have an overhang structure at a lower end area of the vertical trench, forming an insulation layer at the trench with the overhang structure, and forming a passing word-line (PWL) by filling a conductive material at the trench formed the insulation layer.

The performing the second etching may include performing an etching of a side surface area of the vertical trench so that the overhang structure is positioned at a lower part of a storage node in the unit cell.

The overhang structure may have an inclined structure that is extended in width in the unit cell direction from a pre-set center area to a lower end of the vertical trench.

The pre-set center area of the vertical trench may be a storage node (SN) junction area.

The forming the insulation layer may include filling the second etched area with an insulation material.

The unit cell may be a transistor of a saddle fin structure.

In accordance with an embodiment of the disclosure, a semiconductor device includes a substrate, a unit cell area positioned at a pre-set area of the substrate, a trench area disposed at a side surface of the unit cell area, and having an overhang structure such that a lower end is extended to the unit cell area, a passing word-line (PWL) area disposed at the trench area and filled with a conductive material, and an insulation area disposed in the trench, and insulating between the passing word-line area and the substrate.

The overhang structure may be configured such that a portion area is positioned at a lower part of a storage node in the unit cell area.

The overhang structure may have an inclined structure that extends in width in the unit cell direction from a pre-set center area to a lower end of a vertical trench.

The pre-set center area of the vertical trench may be a storage node (SN) junction area.

The overhang structure may be filled with an insulation material.

The unit cell area may include a transistor of a saddle fin structure.

### Effect of Invention

Accordingly, a semiconductor device and a manufacturing method thereof according to an embodiment may reduce a field effect and coupling effect for a unit cell area by forming an overhang structure in a passing word-line area, and improve all of a row-hammer and write operation, a retention functions. Through the overhang structure described above, because an ion implantation process and/or a thermal process is not performed after forming a trench for a passing word-line area, a process simplified production may be possible and there is an effect of cost reduction.

### DESCRIPTION OF DRAWINGS

FIG. 1 is a diagram illustrating a configuration of a DRAM according to an embodiment of the disclosure;

FIG. 2 is a diagram illustrating a structure of a semiconductor device according to an embodiment of the disclosure;

FIG. 3 is a diagram illustrating a structure of a transistor according to an embodiment of the disclosure; and

FIG. 4 to FIG. 9 are cross-sectional diagrams of a process illustrating a manufacturing method of a semiconductor device according to an embodiment of the disclosure.

### BEST MODE

### Detailed Description of Exemplary Embodiments

Before describing the disclosure in detail, a description method of the disclosure and the drawings will be described.

First, terms used in describing the various embodiments of the disclosure are general terms selected considering their function herein. However, the terms may change depending on intention, legal or technical interpretation, emergence of new technologies, and the like of those skilled in the related art. Further, there may be terms arbitrarily selected. In this case, the meaning of the term may be interpreted to the meaning defined in the disclosure, and if there is no specific meaning of the term defined, the term may be interpreted based on the overall context of the disclosure and common technological sense in the related technical field.

In addition, like reference numerals or symbols shown in each accompanied drawing indicate components or elements that perform substantially the same function throughout the specification. For convenience of descriptions and understanding, the same reference numerals or symbols may be used and described in different embodiments. That is, although elements having the same reference numerals are all shown in a plurality of drawings, the plurality of drawings do not mean one embodiment.

In addition, in the embodiments of the disclosure, terms including ordinal numbers such as “first” and “second” may be used to distinguish between elements. The ordinal numbers may be used to distinguish same or like elements from one another and a meaning the term is not limited by the use of the ordinal numbers. In an example, an element combined with an ordinal number should not be limited in an order of use, order of arrangement, and the like by the number. If necessary, each ordinal number may be used inter-changeably.

In the disclosure, a singular expression includes a plural expression, unless otherwise specified. It is to be understood that the terms such as “consist” or “include” are used herein to designate a presence of a characteristic, number, step, operation, element, component, or a combination thereof, and not to preclude a presence or a possibility of adding one or more of other characteristics, numbers, steps, operations, elements, components or a combination thereof.

In addition, in the embodiments of the disclosure, when a certain part is described as connected to another part, this includes not only a direction connection, but also an indirect connection through another medium. In addition, a meaning of a certain part including a certain element may mean that another element can be further included rather than excluding the another element unless otherwise specified.

The disclosure will be described in greater detail below with reference to the accompanied drawings.

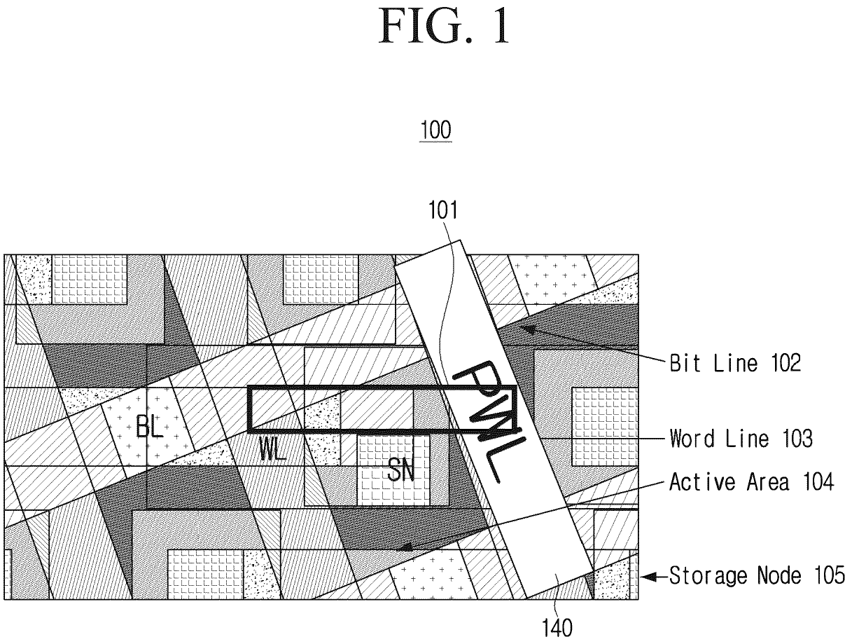

FIG. 1 is a diagram illustrating a configuration of a DRAM according to an embodiment of the disclosure.

Referring to FIG. 1, a DRAM cell from among a plurality of cells that consist the DRAM is shown. The DRAM cell may include a bit line 102, a word line 103, an active area 104, a storage node 105, and a passing word-line 140.

The bit line 102 may be a line for detecting a signal from a cell capacitor, and may be connected to a drain (or source) of a transistor.

The word line 103 may be a signal line which enables the transistor, and disposed with the bit line 102 in a direction that is perpendicular to each other. The word line 103 may be connected to a gate of the transistor to enable the transistor.

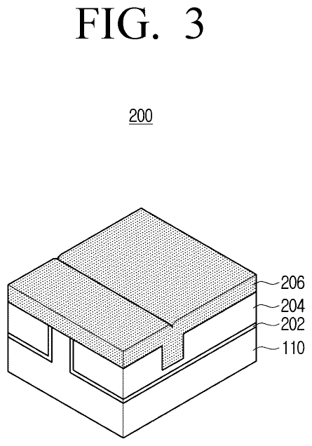

The active area 104 may, as a transistor area, be an area in which a transistor of a saddle fin structure is formed. A specific configuration and operation of the active area 104 will be described below with reference to FIG. 3. In the above, although the transistor of the saddle fin structure being used has been shown and described, transistors of different types such as a fin transistor and a reset transistor may be used at implantation.

The storage node 105 may be a line that is connected to one end of a capacitor.

The passing word-line (or pass word line) 140 may be connected to a source (or drain) of two adjacent transistors, may be in a same direction as the word line 103 as shown in the drawing, and disposed with the bit line 102 in a direction that is perpendicular to each other.

As described above, the passing word-line 140 may provide, based on being disposed adjacently with the storage node 105, an electric-field effect that is generated from and the capacitor which is disposed at a lower end of the storage node 105 and a substrate operation (active area) of a unit cell by an electric-field effed that is generated from the passing word-line 140, and cause a deterioration in a DRAM operation due to a coupling effect and a row-hammer effect.

To remove the effects described above, in the disclosure, one area of a lower end area of the passing word-line 140 is configured to have an overhang structure that is disposed at the lower end of the storage node, and the electric-field and coupling effects are reduced by a signal voltage of the passing word-line.

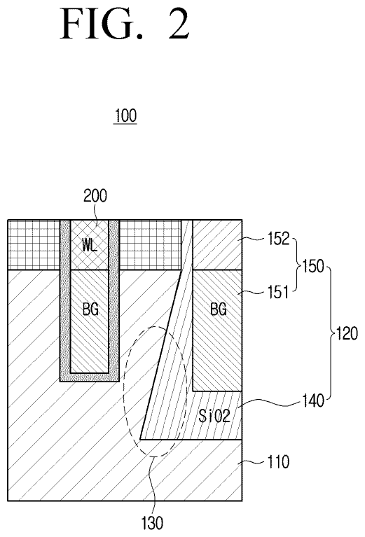

A specific configuration of the overhang structure will be described below with reference to FIG. 2.

FIG. 2 is a cross-sectional diagram illustrating a structure of a semiconductor device according to an embodiment of the disclosure. Specifically, FIG. 2 is a cross-sectional diagram of an area at which BL, WL, SN, and PWL from among a center horizontal line of FIG. 1 are positioned.

Referring to FIG. 2, a semiconductor device 100 may include a substrate 110, a unit cell area 200, a trench area 120, an insulation area 140, and a passing word-line area 150.

The substrate 110 may be a silicon substrate, but is not limited thereto.

The unit cell area 200 may be positioned at a pre-set area of the substrate 110, and although only the word line 103 from among the configurations shown in FIG. 1 has been shown for convenience of description below, remaining configurations that exclude the passing word-line 150 may be disposed on the substrate 110. For example, the transistor of the saddle fin structure may be positioned at the lower end of the word line, and capacitors may be positioned at the word line and the passing word-line. The transistor of the saddle fin structure as described above may have a buried gate (BG) structure as shown in the drawing.

The trench area 120 may be disposed at a side surface of the unit cell area, have an overhang structure 130 in which a lower end is extended to the unit cell area, and the insulation area 140 and the passing word-line 150 are positioned. Specifically, the trench area 120 may have the overhang structure 130 at a lower area of the trench area 120 to reduce the electric-field and coupling effects of the passing word-line 150.

The overhang structure 130 may be an inclined structure which is extended in width toward a cell direction from a pre-set center area to a lower end of the trench, and a portion of an area may be positioned at a lower part of the storage node 105 in the unit cell area. Here, the pre-set center area may be a lower end area from among trench side surfaces at which a trench and a storage node is contacted, that is, a SN (storage node) junction area.

For example, a lower end of the trench may be extended by greater than or equal to 10 nm in a cell direction. The numerical vales provided are merely an example, and may be changed according to a performance and process method of the semiconductor device.

Then, the overhang structure 130 may be filled with an insulation material. Here, the insulation material may be a silicon oxide, a nitride film, an aluminum oxide, a hafnium oxynitride, a zinc oxide, and the like.

The insulation area 140 may be disposed in the trench area 120, and may insulate between the passing word-line area 150 and the substrate 110. The insulation area 140 as described above may be configured such that the silicon oxide (SiO₂) is used, and the nitride, the aluminum oxide, the hafnium oxynitride, the zinc oxide, and the like may be used.

The passing word-line area 150 may be disposed at the trench area 120 and filled with a conductive material. The conductive material may consist of any one from among aluminum (Al), molybdenum (Mo), magnesium (Mg), chromium (Cr), palladium (Pd), gold (Au), nickel (Ni), titanium (Ti), or any combination thereof. The passing word-line area 150 may use two conductive materials 151 and 152 as shown in FIG. 2. That is, a buried gate (BG) may be used.

As described above, the semiconductor device 100 according to an embodiment may reduce the electric-field and coupling effects of the passing word-line area by forming the overhang structure at the passing word-line area.

FIG. 3 is a diagram illustrating a structure of a transistor according to an embodiment of the disclosure.

Referring to FIG. 3, a saddle fin transistor may be formed such that both side surfaces of the active area and an upper surface of the active area are exposed by etching a device isolation layer 204 formed at the substrate 110 of the semiconductor. At the side surface of the active area, an oxide layer (or a nitride layer 202) may be deposited.

Then, a gate 206 may be formed to encapsulate the protruded active area. As described in the above, because a channel is formed at all of the three exposed surfaces of the active area, a current driving characteristic through the channel may be improved.

The gate 206 may be connected to the word line 103 in FIG. 1 as described above.

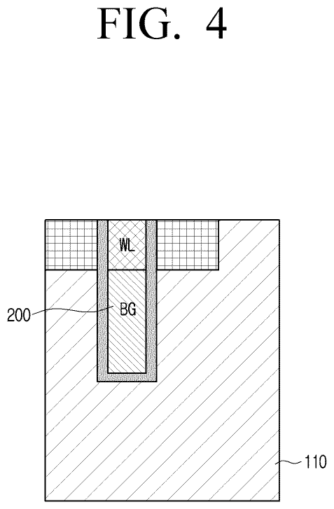

FIG. 4 to FIG. 9 are cross-sectional diagrams of a process illustrating a manufacturing method of a semiconductor device according to an embodiment of the disclosure.

Referring to FIG. 4, first, the substrate 110 on which a unit cell 200 is formed may be prepared. Specifically, a DRAM semiconductor process may be divided into a process for forming the unit cell and a process for forming the PWL.

Specifically, the process for forming the unit cell may include a process for forming the device isolation layer and an ion implantation or well, a lithography and etching process for the word line, a transistor gate oxidization process, an active word line gate deposition process, and the like. When the above-described process for forming the unit cell is performed, a substrate on which the unit cell is formed as shown in FIG. 4 may be prepared.

A process for forming the PWL which uses the corresponding substrate will be described below.

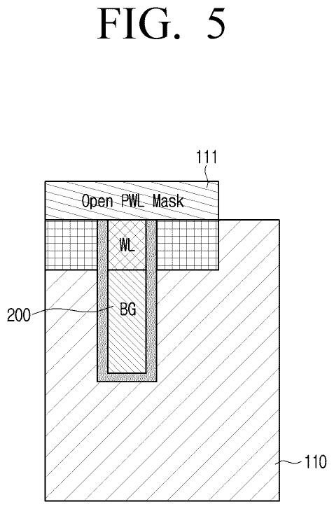

First, as shown in FIG. 5, a mask 111 for forming a passing data line may be formed. Specifically, the mask may be formed at an area excluding the area that corresponds to the trench area at an upper part of the substrate 110.

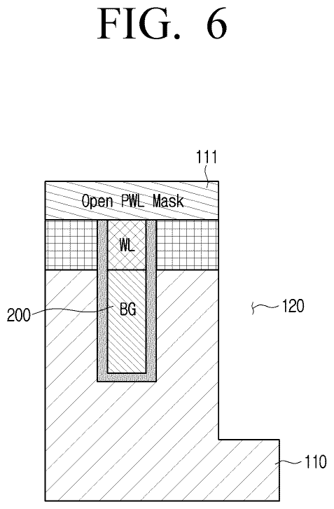

In a following process, as shown in FIG. 6, a first etching may be performed for a vertical trench 120 which is deeper than a lower end of the unit cell 200 (specifically, word line) to be formed at the substrate 110 on which the mask 111 is formed. The etching as described above may be performed in a dry etching method.

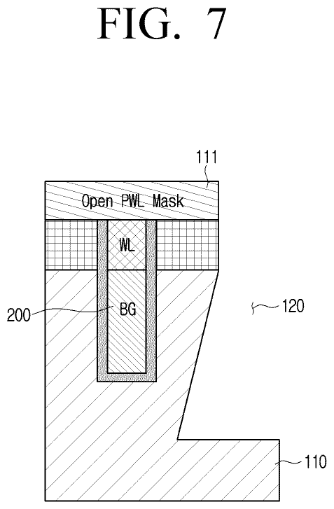

In a following process, as shown in FIG. 7, a second etching may be performed so as to have the overhang structure 130 at a lower area of the vertical trench. Specifically, the second etching may be performed in the dry etching method or a wet etching method, and an etching process may be performed so as to have an inclined form which gradually increases in width from the lower end area from among the trench side surfaces at which the trench and the storage node is contacted, that is, the storage node (SN) Junction area toward a lower end direction of the trench.

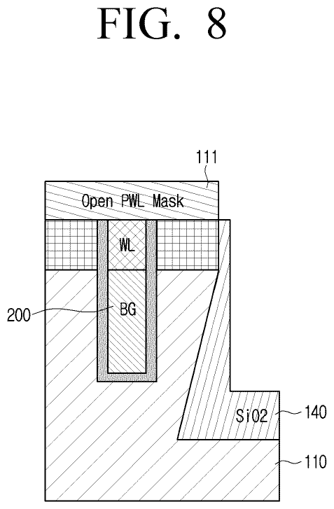

In a following process, as shown in FIG. 8, an insulation layer 140 may be formed at the trench which has the overhang structure. Specifically, the insulation layer may be filled in the overhang structure, and the insulation layer may be formed at the side surface of the trench. Here, the insulation layer may consist of silicon oxide, nitride, aluminum oxide, hafnium oxynitride, zinc oxide, and the like.

Although the ion implantation process such as a tunneling implant has been performed after the above-described etching operation in the related art, because the electric-field and coupling effects are reduced due to the overhang structure in the disclosure, a following process may be performed without performing a separate ion implantation process (specifically, a process for improving dispersion (ion implantation and thermal processes)).

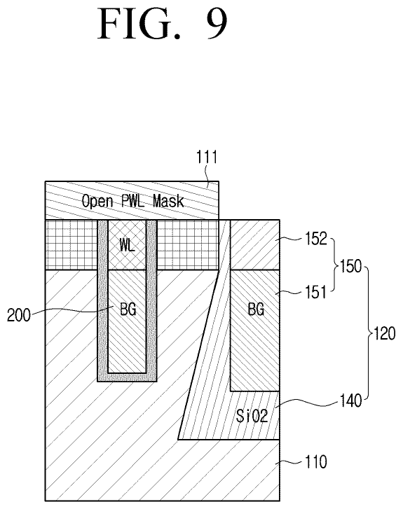

In a following process, as shown in FIG. 9, the passing word-line 150 may be formed by filling the conductive material in the trench in which the insulation layer is formed. At this time, the passing word-line may be formed by using two types of conductive materials 151 and 152. By performing the process as described above, the semiconductor device as shown in FIG. 2 may be formed.

The semiconductor manufacturing method according to the disclosure as described above may form the overhang structure for reducing electric-field by simply adding a second etching process, and the ion implantation process and/or the thermal process which have been performed in the related art accordingly thereto may be omitted.

While the disclosure has been shown and described with reference to the example embodiments thereof, the disclosure is not limited to the embodiments specifically described and various modifications may be made therein by those skilled in the art to which this disclosure pertains without departing from the spirit and scope of the disclosure, and such modifications shall not be understood as separate from the technical concept or outlook of the present disclosure.

What is claimed is:

1. A manufacturing method of a semiconductor device, the method comprising:
preparing a substrate on which a unit cell is formed;
forming a mask for forming a passing word-line on the substrate;
performing a first etching for a vertical trench, which is deeper than a lower end of the unit cell, to be formed at the substrate on which the mask is formed;
performing a second etching so as to have an overhang structure at a lower end area of the vertical trench;
forming an insulation layer at the trench with the overhang structure; and
forming a passing word-line (PWL) by filling a conductive material at the trench in which the insulation layer.

2. The method of claim 1, wherein
the performing the second etching comprises,
performing an etching of a side surface area of the vertical trench so that the overhang structure is positioned at a lower part of a storage node in the unit cell.

3. The method of claim 1, wherein
the overhang structure has an inclined structure that is extended in width in the unit cell direction from a pre-set center area to a lower end of the vertical trench.

4. The method of claim 3, wherein
the pre-set center area of the vertical trench is a storage node (SN) junction area.

5. The method of claim 1, wherein
the forming the insulation layer comprises,
filling the second etched area with an insulation material.

6. The method of claim 1, wherein
the unit cell is a transistor of a saddle fin structure.

7. A semiconductor device, comprising:
a substrate;
a unit cell area positioned at a pre-set area of the substrate;
a trench area disposed at a side surface of the unit cell area, and having an overhang structure such that a lower end is extended to the unit cell area;
a passing word-line (PWL) area disposed at the trench area and filled with a conductive material; and
an insulation area disposed in the trench area, and insulating between the passing word-line area and the substrate.

8. The semiconductor device of claim 7, wherein
the overhang structure is configured such that,
a portion area is positioned at a lower part of a storage node in the unit cell area.

9. The semiconductor device of claim 7, wherein
the overhang structure has an inclined structure that extends in width in the unit cell direction from a pre-set center area to a lower end of a vertical trench.

10. The semiconductor device of claim 9, wherein
the pre-set center area of the vertical trench is a storage node (SN) junction area.

11. The semiconductor device of claim 7, wherein
the overhang structure is filled with an insulation material.

12. The semiconductor device of claim 7, wherein
the unit cell area comprises a transistor of a saddle fin structure.
